(19) United States
(12) Patent Application Publication
(10) Pub. No.: US 2026/0164976 A1
(43) Pub. Date: Jun. 11, 2026

(54) PIXEL ARRANGEMENT STRUCTURE, METAL MASK, DISPLAY PANEL AND DISPLAY DEVICE

(71) Applicant: Everdisplay Optronics (Shanghai) Co., Ltd., Shanghai (CN)

(72) Inventors: Yinan LIANG, Shanghai (CN); Yingjun LIU, Shanghai (CN); Chung Che TSOU, Shanghai (CN); Xu ZENG, Shanghai (CN); Shaodong MA, Shanghai (CN); Kaikai CHEN, Shanghai (CN); Wei SANG, Shanghai (CN); Jun HU, Shanghai (CN)

(73) Assignee: Everdisplay Optronics (Shanghai) Co., Ltd., Shanghai (CN)

(21) Appl. No.: 18/708,226

(22) PCT Filed: Mar. 1, 2023
(86) PCT No.: PCT/CN2023/079012

§ 371 Date: May 8, 2024

(30) Foreign Application Priority Data
Dec. 20, 2022 (CN) 202211640036.7

(51) Int. Cl. H10K 59/35

(52) U.S. Cl. CPC H10K 59/353; H10K 59/352

(57) ABSTRACT

The present disclosure provides a pixel arrangement structure, a metal mask, a display panel and a display device, and the pixel arrangement structure includes a first sub-pixel located at a first vertex of a first virtual polygon; a second sub-pixel located at a second vertex of the first virtual polygon, the first vertex and the second vertex being arranged alternately and spaced apart; and a third sub-pixel located inside the first virtual polygon, wherein two first sub-pixels are arranged at each first vertex, and a line connecting centers of third sub-pixels in two adjacent first virtual polygons is parallel to a row direction or a column direction. The present disclosure not only solves the jagged display problem of the OLED display device, but also is beneficial to improving the pixel density of the OLED display device.

### CROSS-REFERENCE TO RELATED APPLICATION

The present application is a US national phase of International Application No. PCT/CN2023/079012, filed on Mar. 1, 2023, which is based upon and claims priority to Chinese Patent Application No. 202211640036.7, filed on Dec. 20, 2022, the entire contents of both of which are incorporated herein by reference.

### TECHNICAL FIELD

The present disclosure relates to the technical field of display, and in particular to a pixel arrangement structure, a metal mask, a display panel and a display device.

### BACKGROUND

With the development of display technologies, the importance and requirements of display effect of an Organic Light-emitting Diode (OLED) panel are increasing. Presently, the common pixel design is that three sub-pixels of red, green and blue are combined to form a pixel unit, and a display light-emitting area is formed by filling an array of the pixel units.

Referring to FIG. 1, in a Real Rendering arrangement in the related art, each pixel unit includes a red sub-pixel 11, a blue sub-pixel 12 and a green sub-pixel 13. The relative positions of the centers of the green sub-pixels 13 in the pixel units are changed, that is, the centers of the green sub-pixels 13 are not in the same straight line. Since human eyes are most sensitive to the green sub-pixels, if the positions of the green sub-pixels are changed, a problem of a jagged display effect occurs at the edge of the display area of the display panel.

In another aspect, with the wide attention on the high screen display effect of the display device, higher and higher requirements are posed on high resolution of the display device, especially in the OLED display devices, and the OLED display devices having a high Pixels Per Inch (PPI) are gradually coming into people's sight.

It is to be noted that the information disclosed above in the background is only for enhancement of understanding of the background of the present disclosure and therefore may include information that does not constitute prior art known to a person of ordinary skill in the art.

### SUMMARY

The present disclosure provides a pixel arrangement structure, a metal mask, a display panel and a display device.

According to an aspect of the present disclosure, there is provided a pixel arrangement structure including:
a first sub-pixel located at a first vertex of a first virtual polygon;
a second sub-pixel located at a second vertex of the first virtual polygon, the first vertex and the second vertex being arranged alternately and spaced apart;
a third sub-pixel located inside the first virtual polygon;
wherein two first sub-pixels are arranged at each first vertex, and a connecting line of centers of the third sub-pixels in two adjacent first virtual polygons is parallel to a row direction or a column direction.

According to another aspect of the present disclosure, there is provided a metal mask for fabricating any one of the above pixel arrangement structures, including:
a plurality of aperture regions, a shape of each of the aperture regions corresponding to each sub-pixel being matched with an outer contour shape of the sub-pixel; two first sub-pixels located on the same vertex of the first virtual polygon share the same aperture region; the aperture regions corresponding to the sub-pixels with different colors are tangent with respect to a tangent line segment, and any two of the aperture regions corresponding to three adjacent sub-pixels are tangent with respect to each other.

According to another aspect of the present disclosure, there is provided a display panel comprising any one of the above pixel arrangement structures.

According to another aspect of the present disclosure, there is provided a display device including the above display panel.

### BRIEF DESCRIPTION OF THE DRAWINGS

The accompanying drawings, which are incorporated in and constitute a part of the description, illustrate embodiments consistent with the present disclosure and together with the description, serve to explain the principles of the present disclosure. It is obvious that the drawings in the following description are only some embodiments of the present disclosure, and that for a person skilled in the art, other drawings can be derived from these drawings without inventive effort.

FIG. 1 is a schematic diagram of a pixel arrangement structure in the related art;

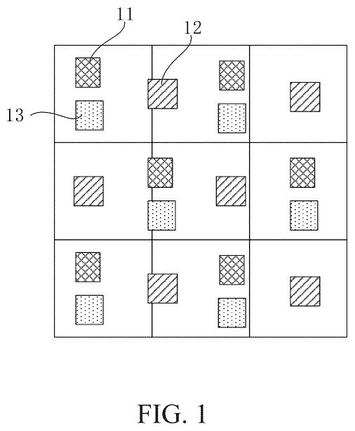

FIG. 2 is a schematic structural diagram of a display panel according to an embodiment of the present disclosure;

FIG. 3 is a schematic diagram of a pixel arrangement structure according to an embodiment of the present disclosure;

FIG. 4 is a schematic structural diagram of a first type of pixel unit involved in a pixel arrangement structure according to an embodiment of the present disclosure;

FIG. 5 is a schematic structural diagram of a second type of pixel unit involved in a pixel arrangement structure according to an embodiment of the present disclosure;

FIG. 6 is a schematic structural diagram of a third type of pixel unit involved in a pixel arrangement structure according to an embodiment of the present disclosure;

FIG. 7 is a schematic diagram of a pixel arrangement structure according to another embodiment of the present disclosure;

FIG. 8 is a schematic structural diagram of a pixel unit involved in the pixel arrangement structure disclosed in FIG. 7;

FIG. 9 is a schematic diagram of a pixel arrangement structure and an aperture structure of a metal mask corresponding to the pixel arrangement structure according to another embodiment of the present disclosure; and

FIG. 10 is a schematic diagram of a driving structure for a display panel according to an embodiment of the present disclosure.

### DETAILED DESCRIPTION

The example embodiments will now be described more fully with reference to the accompanying drawings. The example embodiments may, however, be embodied in many different forms and should not be construed as being limited to the embodiments set forth herein. Rather, these embodiments are provided so that the present disclosure will be thorough and complete, and the concept of the example embodiments are fully conveyed to those skilled in the art. The features, structures, or characteristics described may be combined in any suitable manner in one or more embodiments. In the following description, numerous specific details are provided to give a thorough understanding of the embodiments of the present disclosure. Those skilled in the art will recognize, however, that the technical solutions of the present disclosure can be practiced without one or more of the specific details, or with other methods, materials, devices, etc. In other instances, well-known technical solutions have not been shown or described in detail to avoid obscuring aspects of the present disclosure. The same reference numerals in the drawings denote the same or similar structures, and thus detailed description thereof will be omitted.

The terms “a”, “an”, “the”, “said” and “at least one” are used to indicate the presence of one or more elements/components/parts/and so on; the terms “comprising,” “having” and “providing” are intended to be inclusive in open-ended meanings and mean that there may be additional elements/components/and so on in addition to the elements/components/and so on listed.

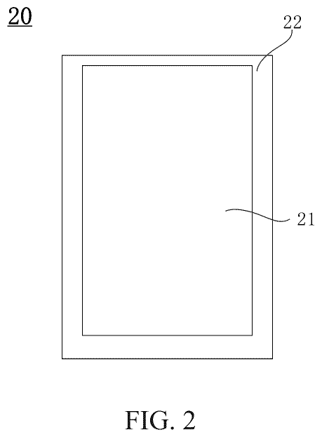

As shown in FIG. 2, an embodiment of the present disclosure discloses a display panel 20. The display panel 20 includes a display area 21 and a non-display area 22, and the display area 21 displays images by a plurality of sub-pixels. Specifically, in some embodiments, the display area 21 may be a rectangular, and the non-display area 22 is disposed around the display area 21. Of course, the shapes and arrangements of the display area 21 and the non-display area 22 include, but are not limited to, the above examples. For example, when the display panel 20 is used for a wearable device worn on a user, the display area 21 may have a circular shape like a watch; when the display substrate is used for display on a vehicle, the display area 21 and the non-display area 22 may have a circular shape, a polygonal shape, or other shapes. The display area 21 is provided with a plurality of sub-pixels emitting light of different colors, and for example, white light can be formed by color mixing of red light, green light, and blue light. The sub-pixel is characterized as the minimum unit for emitting light (e.g., the minimum addressable unit of the display panel 20).

The display panel 20 provided in the embodiments of the present disclosure may be an organic light-emitting display panel, and the sub-pixel includes at least an anode, a cathode, and a light-emitting layer located between the anode and the cathode. A pixel driving circuit applies a voltage across the anode and the cathode to excite migration of carriers, which acts on the light-emitting layer so as to emit light. Specifically, the light-emitting layer includes at least a hole transport layer, an organic material layer and an electron transport layer, the anode is an electrode used for providing holes for the hole transport layer or for transporting the holes, and the cathode is used for providing electrons for the organic material layer or for transporting the electrons.

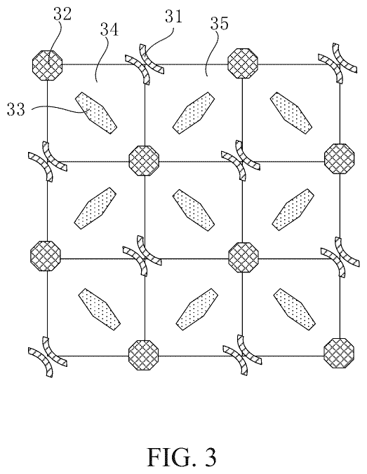

As shown in FIG. 3, an embodiment of the present disclosure discloses a pixel arrangement structure. In the embodiment of the present disclosure, the pixel arrangement structure includes first sub-pixels 31, second sub-pixels 32 and third sub-pixels 33 that emit different colors of light. The first sub-pixel 31, the second sub-pixel 32, and the third sub-pixel 33 may be one of a blue sub-pixel, a red sub-pixel, and a green sub-pixel, respectively, and constitute one pixel presenting white light. Of course, in some other embodiments, the first sub-pixel 31, the second sub-pixel 32, and the third sub-pixel 33 may be other colors than red, green, and blue, and are not limited herein.

The pixel arrangement structure includes a plurality of first virtual polygons, and the plurality of first virtual polygons are arranged in a manner of sharing edges to form a pixel array. In the array, distribution of positions of sub-pixels in the first virtual polygon in the N-th row is different from the distribution of the positions of the sub-pixels in the first virtual polygon in the (N+1)-th row. The distribution of the positions of the sub-pixel position in the first virtual polygon in the N-th row is the same as the distribution of the positions of the sub-pixels in the first virtual polygon in the (N+2)-th row.

Specifically, referring to FIG. 3, in the present embodiment, the first virtual polygon is a quadrilateral, that is, a first virtual quadrilateral. The first virtual quadrilateral has four vertexes, namely two opposite first vertexes and two opposite second vertexes. The first and second vertexes are arranged alternately and spaced apart. A group of first sub-pixels 31 is provided at each first vertex. Each group of the first sub-pixels 31 includes two first sub-pixels 31 disposed in central symmetry about the first vertex. The two groups of first sub-pixels 31 are respectively located at two first vertices, and two second sub-pixels 32 are respectively located at two second vertices. The third sub-pixel 33 is located inside the first virtual quadrilateral. That is, the third sub-pixel 33 is surrounded by four first sub-pixels 31 and two second sub-pixels 32. As such, the arrangement of the sub-pixels is more compact, which is beneficial to improving an aperture ratio of the sub-pixels.

That is to say, two groups of first sub-pixels 31 are opposed in the first virtual quadrilateral, and two second sub-pixels 32 are opposed in the first virtual quadrilateral. The absolute positions of the first vertices and the second vertices in the first virtual quadrilateral are not fixed. It can be understood that in some other embodiments, the first virtual polygon may have other shapes, such as a pentagon, a hexagon, etc., which is not limited in the present disclosure.

It should be noted that the sub-pixel being located at a certain position refers to a position range where the sub-pixel is located, as long as it ensures that the sub-pixel overlaps with the position. In the embodiment shown in FIG. 3, the centers of the two groups of first sub-pixels 31 may overlap with two opposite vertices of the first virtual quadrilateral, respectively, and the centers of the two second sub-pixels 32 may overlap with two other opposite vertices of the first virtual quadrilateral, respectively.

In an embodiment, a line connecting centers of the third sub-pixels 33 in two adjacent first virtual polygons is parallel to the row direction or the column direction. That is, the centers of the third sub-pixels 33 located on the same row or the same column are located in the same straight line. The line connecting the centers of the third sub-pixels 33 located on the same row is parallel to the row direction, and the line connecting the centers of the third sub-pixels 33 located on the same column is parallel to the column direction. For example, the row direction and the column direction may be a row direction and a column direction of the pixel array.

In an embodiment, for example, the first sub-pixel 31 is a blue sub-pixel, the second sub-pixel 32 is a red sub-pixel, and the third sub-pixel 33 is a green sub-pixel, and it is not limited thereto in the present disclosure. It achieves that the green sub-pixels, which the human eyes are most sensitive to, are placed in the first virtual quadrilateral, thereby preventing color shift.

In an embodiment, two first sub-pixels 31 in the group of first sub-pixels 31 disposed at each of the first vertices are symmetrically disposed; i.e. two first sub-pixels 31 located at the same first vertex are symmetrically disposed. Accordingly, feasibility of manufacturing a mask corresponding to the pixel arrangement structure can be enhanced, and the difficulty in manufacturing the mask can be reduced. Meanwhile, the aperture ratio of the sub-pixels can be ensured. That is, it takes account for both the aperture ratio of the sub-pixels and the manufacturing difficulty of the mask. The two groups of first sub-pixels 31 arranged in each first virtual quadrilateral can be arranged in a mirror symmetry manner or in an asymmetrical manner.

Continuing to referring to FIG. 3, in this embodiment, the minimum repeating unit of the pixel arrangement structure is composed of four repeating units. The four repeating units are two first repeating units 34 and two second repeating units 35, respectively. The first repeating units 34 and the second repeating units 35 are alternately and adjacently arranged in a manner of sharing a common edge. The first diagonal line formed by two groups of first sub-pixels 31 in the first repeating unit 34 and the second diagonal line formed by two groups of first sub-pixels 31 in the adjacent second repeating unit 35 form an included angle, that is, the first diagonal line and the second diagonal line are in an intersecting relationship, but not a parallel relationship. The minimum repeating units are repeatedly arranged in the row direction, the column direction and the 45-degree direction to form a whole pixel arrangement structure.

In an embodiment of the present disclosure, the pixel arrangement structure includes a plurality of pixel units (pixels). Each of the pixel units is composed of two first sub-pixels 31, two second sub-pixels 32, and one third sub-pixel 33. Alternatively, each of the pixel units may be composed of two first sub-pixels 31, one second sub-pixel 32 and two third sub-pixels 33. Compared with the Real Rendering pixel arrangement mode or the Diamond arrangement mode in the related art, in an aspect, the present disclosure can enable geometric centers of the green sub-pixels positioned in the same row or the same column to be in the same straight line, thereby avoiding the jagged display problem, and in another aspect, each of the pixel units in the present disclosure includes five sub-pixels, and the more sub-pixels are beneficial to improving the display effect of the OLED display device.

In the present embodiment, two first sub-pixels 31 are disposed at each first vertex, so that the number of sub-pixels included in the entire pixel array of the display panel is greater, the number of sub-pixels borrowed by the adjacent pixel units is smaller compared with the related art, and the number of sub-pixels not borrowed by the adjacent pixel units is greater, thereby increasing the real PPI of the display panel. Compared with the pixel arrangement structure in the related art in which each pixel unit also includes five sub-pixels, currently, only the equivalent PPI is improved by pixel borrowing between adjacent virtual pixel units, and the real PPI cannot be improved, while the display effect is more exquisite in the embodiment of the present disclosure, and the display effect of the OLED display device is favorably improved. In another aspect, in an implementation where the sub-pixels are connected with the pixel driving circuit, two blue sub-pixels can be separately driven, which reduces the probability of poor screen luminescence is reduced.

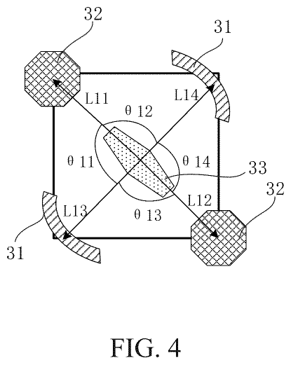

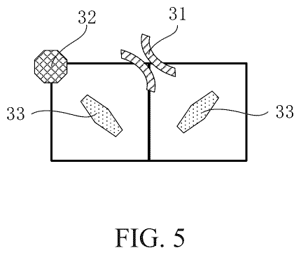

In a specific implementation, each pixel unit may have one or two first sub-pixels 31 at one first vertex. Referring to FIG. 4 and FIG. 5, one pixel unit is shown. A first type of pixel unit corresponding to FIG. 4 has a first sub-pixel 31 at a first vertex. Specifically, the pixel unit includes two first sub-pixels 31, two second sub-pixels 32, and one third sub-pixel 33. The two first sub-pixels 31 included in the pixel unit are respectively located at two opposite vertices of the first virtual quadrilateral. In this case, the connecting lines of centers of all the sub-pixels in the pixel unit form a second virtual quadrilateral. The third sub-pixel 33 is located inside the second virtual quadrilateral.

A second type of pixel unit corresponding to FIG. 5 has two first sub-pixels 31 at a first vertex. Specifically, the pixel unit includes two first sub-pixels 31, one second sub-pixel 32, and two third sub-pixels 33. The two first sub-pixels 31 included in the pixel unit are located at the same vertex of the first virtual quadrilateral. In this case, the connecting lines of centers of all the sub-pixels in the pixel unit form a second virtual quadrilateral. The third sub-pixels 33 are located at vertices of the second virtual quadrilateral. For example, the two third sub-pixels 33 each is located at a respective vertex.

Continuing to refer to FIG. 4, in some embodiments, in the first virtual quadrilateral, a first distance between the center of the third sub-pixel 33 and each of the centers of the two second sub-pixels 32 adjacent to the third sub-pixel 33 is equal, i.e., L11 and L12 are equal to each other. A second distance between the center of the third sub-pixel 33 and each of the centers of the two first sub-pixels 31 adjacent to the third sub-pixel 33 is equal, i.e., L13 and L14 are equal to each other. The first distance is not equal to the second distance. That is, L12≠L13, i.e., (L11=L12)≠(L13=L14). Besides, the following requirements can be met: among center connecting lines formed by the center of the third sub-pixel 33 and the center of any of the sub-pixels adjacent to the third sub-pixel 33, the included angle between any two adjacent ones of the center connecting lines is 90°. That is, θ11=θ12=θ13=θ14=90°. This embodiment can take account for both the aperture ratio of the sub-pixels and the manufacturing difficulty of the mask, and can reduce the manufacturing difficulty of the mask while ensuring the aperture ratio of the sub-pixels; that is, the service life of the display panel and the manufacturing difficulty of the mask are both taken into account.

In some embodiments, among the center connecting lines formed by the center of the third sub-pixel 33 and the center of any of the sub-pixels adjacent to the third sub-pixel 33, a smaller included angle formed between two adjacent center connecting lines is larger than 72° and smaller than 83°, for example, 72°<θ12<83°, and in this embodiment, it can take account for both the aperture ratio of the sub-pixels and the manufacturing difficulty of the mask, thereby reducing the manufacturing difficulty of the mask while ensuring the aperture ratio of the sub-pixels, i.e., improving the lifetime of the display panel.

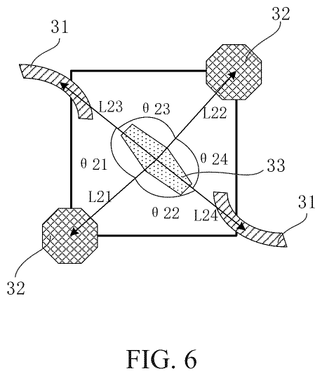

In some embodiments, reference is made to FIG. 6, which shows a schematic structural diagram of a third type of pixel unit. In the corresponding first virtual quadrilateral, a third distance between the center of the third sub-pixel 33 and the center of each of the two second sub-pixels 32 adjacent to the third sub-pixel 33 is equal, i.e., L21 and L22 are equal to each other. A fourth distance between the center of the third sub-pixel 33 and the center of each of the two first sub-pixels 31 adjacent to the third sub-pixel 33 is equal, i.e., L23 and L24 are equal to each other. The third distance is not equal to the fourth distance. That is, L22≠L23, i.e., (L21=L22)≠L23=L24. Besides, the following requirements can be met: among the center connecting lines formed by the center of the third sub-pixel 33 and the center of any of the sub-pixels adjacent to the third sub-pixel 33, each included angle formed between any two adjacent ones of the center connecting lines is not equal; and the center of the third sub-pixel 33 overlaps with the extending direction of the center connecting line of the adjacent sub-pixels with the same color. That is, (θ22=θ23)≠(θ21=θ24)≠90°. Besides, the following requirements are met: θ21 +θ22=180°; and θ23+θ24=180°.

In some embodiments, among the center connecting lines formed by the center of the third sub-pixel 33 and the center of any of the adjacent sub-pixels, a smaller included angle formed between two adjacent ones of the center connecting lines is larger than 72° and smaller than 83°, for example, 72°<θ23<83°, and in this embodiment, it can take account for both the aperture ratio of the sub-pixels and the manufacturing difficulty of the mask, thereby reducing the manufacturing difficulty of the mask while ensuring the aperture ratio of the sub-pixels, i.e., improving the lifetime of the display panel.

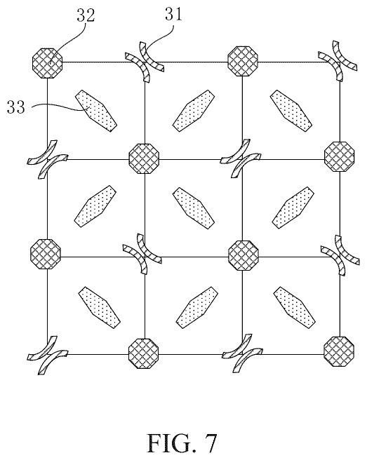

FIG. 7 shows a pixel arrangement structure according to another embodiment of the present disclosure. In this structure, the two groups of first sub-pixels 31 disposed at the first vertices on the opposite corners of the first virtual quadrilateral have asymmetric structures, that is, the two groups of blue sub-pixels have asymmetric structures. Specifically, in this embodiment, the first sub-pixels 31 in one of the two groups of first sub-pixels 31 are symmetric about a first virtual symmetry line, the first sub-pixels 31 in the other group is symmetric about a second virtual symmetry line, and the first virtual symmetry line and the second virtual symmetry line form an included angle. That is, the first virtual symmetry line and the second virtual symmetry line are not parallel to each other. In this embodiment, the edge shape of blue display is changed by rotating a group of first sub-pixels 31, namely the blue sub-pixels, corresponding to one of the first vertices of the first virtual quadrilateral, which mitigates the display problem of color edges and alleviates the black line problem of blue single-color oblique line display, and thus is beneficial to improving the display effect of the display panel employing the pixel arrangement structure.

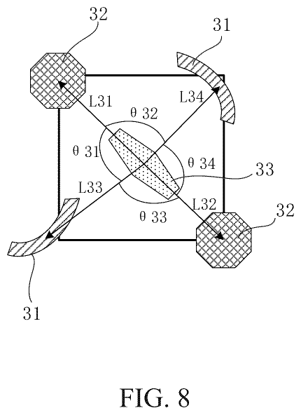

FIG. 8 shows a schematic diagram of a structure of the pixel unit corresponding to FIG. 7. In the first virtual quadrilateral corresponding to the pixel unit, a fifth distance between the center of the third sub-pixel 33 and the center of each of the two second sub-pixels 32 adjacent to the third sub-pixel 33 is equal, i.e., L31 and L32 are equal to each other. A sixth distance between the center of the third sub-pixel 33 and the center of each of the two first sub-pixels 31 adjacent to the third sub-pixel 33 is not equal, that is, L33 and L34 are not equal to each other. L32 and L33 are not equal to each other. That is, (L31=L32)≠L33≠L34.

The first connecting lines are respectively formed between the centers of the third sub-pixel 33 and the centers of the second sub-pixels 32 adjacent to the third sub-pixel 33, the second connecting lines are respectively formed between the center of the third sub-pixel 33 and the centers of the first sub-pixels 31 adjacent to the third sub-pixel 33, the first included angles formed between each of two first connecting lines and one of the second connecting lines is 90 degrees, the second included angle and third included angle are respectively formed between the two first connecting lines and another one of the second connecting lines, and the first included angle, the second included angle and the third included angle are not equal to each other. That is, 90°=θ32=θ34≠θ31≠θ33. Meanwhile, the following is satisfied: θ31+θ33=180°; and θ32+θ34=180°. In some embodiments, 72°<θ31<83°, so that the aperture ratio of the sub-pixels and the manufacturing difficulty of the mask can be both taken into account, thereby reducing the manufacturing difficulty of the mask while ensuring the aperture ratio of the sub-pixels, i.e., improving the lifetime of the display panel.

In the drawings of the present disclosure, the first sub-pixel 31 is in a crescent shape, the second sub-pixel 32 is in an octagonal shape, and the third sub-pixel 33 is in a hexagonal shape. It is understood that in some other embodiments, the shapes of the first sub-pixel 31, the second sub-pixel 32 and the third sub-pixel 33 may be other shapes, such as a quadrilateral, a hexagon, an octagon or a rounded quadrilateral with rounded corners, a rounded hexagon or a rounded octagon, which are not limited herein.

It should be understood that the different colors of light have different wavelengths, and the higher wavelength means higher energy of the light, the light with higher energy tends to cause decay of the organic light-emitting material, making it easier for the sub-pixels emitting photons of high energy to decay. The blue light wavelength is shorter than the red light wavelength and the green light wavelength, and thus the energy of the blue light is higher, and the organic light-emitting material emitting the blue light is prone to decay, which causes the light emitted in the pixel unit to tend to be red, resulting in color deviation phenomenon of the white light. Therefore, in the embodiments of the present disclosure, the light-emitting area (pixel aperture area) of the blue sub-pixel (first sub-pixel 31) is larger than the light-emitting areas of the red sub-pixel (second sub-pixel 32) and the green sub-pixel (third sub-pixel 33). Accordingly, the problem of poor display caused by different attenuation rates of the organic light-emitting materials emitting light of different colors can be alleviated to a certain extent.

It should be noted that, since the human eyes are sensitive to green light, in some embodiments, the light-emitting area of the green sub-pixel may be smaller than that of the red sub-pixel, and of course, in some other embodiments, the light-emitting area of the green sub-pixel may be equal to that of the red sub-pixel, which is not limited herein.

It should be noted that all center connecting lines involved in the embodiments of the present disclosure are virtual connecting lines, but not actual connection lines.

It should be noted that the shapes shown in the above-mentioned embodiments of the present disclosure are only examples that satisfy the conditions, and any polygonal shapes such as triangle, rectangle, hexagon, etc., circular shapes and other shapes also fall within the scope of the present disclosure. In above illustrations in the present disclosure, though the blue sub-pixel is used as the split sub-pixel, using the red sub-pixel, green sub-pixel, etc. as the split sub-pixel also fall within the scope of the present disclosure.

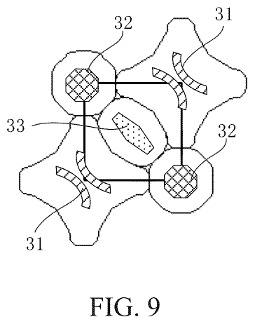

Some embodiments of the present disclosure also provide a metal mask. The metal mask is used for manufacturing the pixel arrangement structure disclosed in any one of the above embodiments. For detailed structural features and advantages of the pixel arrangement structure, reference may be made to the description of the above embodiments, which are not repeated herein. The metal mask includes a plurality of aperture regions corresponding to shapes and positions of the first, second, or third sub-pixels 31, 32, or 33. Referring to FIG. 9, in this embodiment, the shape of the aperture region corresponding to each sub-pixel matches the outer contour shape of each sub-pixel. The open regions corresponding to the sub-pixels with different colors are tangent with respect to a tangent line segment, rather than with respect to a tangent point. And any two of the aperture regions corresponding to three adjacent three sub-pixels are tangent with each other with respect to the tangent line segment. Therefore, the apertures of the metal mask are densely arranged by adjusting the shape of the sub-pixels.

As such, it is beneficial to improving the aperture ratio of the sub-pixels, so that the pixel arrangement has a higher space utilization rate, thereby avoiding the problems that the display brightness requirements for the OLED display device can be met only by increasing the driving current and that working under high driving current can easily lead to device aging under the condition of the same resolution, and prolonging the service life of the OLED display device. In some embodiments, the two first sub-pixels located at the same vertex of the first virtual polygon share the same aperture region, which is beneficial to further improving the aperture ratio of the sub-pixels.

In some embodiments, the first sub-pixel 31 is in a crescent shape enclosed by four line segments, a first line segment of the four line segments is disposed opposite to a second line segment of the outer contour of the second sub-pixel 32, and the extending direction of the first line segment is parallel to the extending direction of the second line segment, so that the aperture region corresponding to the first sub-pixel 31 is tangent to the aperture region corresponding to the second sub-pixel 32. Similarly, the extending direction of one of the four line segments of the outer contour of the first sub-pixel 31 may also be designed in parallel with the extending direction of line segments disposed oppositely in the outer contour of the third sub-pixel 33. The extending direction of a line segment of the outer contour of the second sub-pixel 32 may also be designed in parallel with the extension direction of line segment disposed oppositely in the outer contour of the third sub-pixel 33. As such, the apertures of the metal mask are completely densely arranged, which is beneficial to improving the aperture ratio of the sub-pixels is improved and makes the space utilization rate of the pixel arrangement be higher.

In some embodiments, referring to FIG. 9, the second sub-pixel 32, i.e. the red sub-pixel, is in an octagonal shape such that it is tangent to the first sub-pixel 31, i.e. the blue sub-pixel, in the 0° and 90° directions, and is tangent to the third sub-pixel 33, i.e. the green sub-pixel, in the 45° and 135° directions. The green sub-pixel has a hexagonal or drum shape and is tangent to the red sub-pixel in the 45° and 135° directions, and is tangent to the blue sub-pixel in its vertical direction, and the shape thereof may be an arc or a multi-segment line.

The outer contour of the blue sub-pixel adjacent to the green sub-pixel can be designed in corporation to be an arc or a multi-segment line, and similarly, the blue sub-pixel is tangent to the red sub-pixel in the 0° and 90° directions. The adjacent edges of a group of blue sub-pixels symmetrically distributed at the same virtual pixel corner point can be designed to be a section of circular arc, which in one aspect can ensure the minimum influence by the manufacturing limit of the limit manufacturing process distance of the adjacent sub-pixels, and in another aspect can achieve larger utilizing space by connection through the selected arc lines instead of the straight lines, which is beneficial to improving the aperture ratio of the sub-pixels.

In some embodiments, a display panel employing the above pixel arrangement structure may include a pixel definition layer that defines a plurality of pixel apertures, and the light-emitting layers of the sub-pixels are disposed in the pixel apertures. In FIG. 9, an inner edge of each sub-pixel is referred to as a pixel edge, i.e., a boundary of a pixel aperture in the pixel definition layer (PDL layer), and the outer edge is referred to as a virtual edge of the sub-pixel. The virtual edge refers to an outer boundary of the sub-pixel when being blocked by the mask. The distance between the sub-pixels refers to the minimum distance between adjacent pixel edges of the sub-pixels.

Some embodiments of the present disclosure also provide a display panel including the pixel arrangement structure disclosed in any of the above embodiments. For detailed structural features and advantages of the pixel arrangement structure, reference may be made to the description of the above embodiments, which are not repeated herein. In the present disclosure, two first sub-pixels 31 in each group of first sub-pixels 31 may be respectively provided with an anode layer, or may share a bottom anode layer. Therefore, the display panel employing the pixel arrangement structure can adopt different panel driving modes according to requirements. For example, two adjacent blue sub-pixels can share the bottom anode layer, so that one data signal line is used for driving of light emission in common. Alternatively, the two blue sub-pixels may be separately driven by using two data signal lines. Alternatively, the two blue sub-pixels may be separately connected and driven by one data signal line.

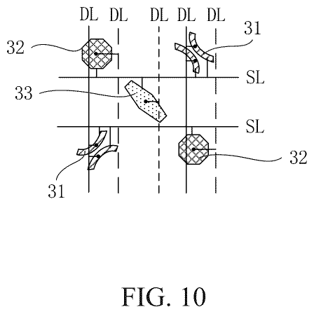

FIG. 10 shows a driving structure for the above display panel. The horizontal solid lines are scanning signal lines SL, the vertical dotted lines are data signal lines DL, and the scanning signal lines SL and the data signal lines DL are orthogonally arranged. Referring to FIG. 10, in this embodiment, two first sub-pixels 31 in each group of first sub-pixels 31 each includes an anode layer, and two anode layers corresponding to the two first sub-pixels 31 are respectively connected to a same data signal line, that is, separately connected to and driven by the same data signal line. As such, if one of the first sub-pixels 31 is damaged, the other first sub-pixel 31 can support pixel to normally emit light through parameter adjustment, reducing the possibility of bad points and the like.

Some embodiments of the present disclosure also provide a display device including the display panel disclosed in the above embodiments.

The display device provided by the embodiments of the present disclosure may be any device that displays images, whether in motion (e.g., video) or stationary (e.g., still images), and whether in text or in image. More particularly, it is contemplated that the embodiments may be implemented in or associated with a variety of electronic devices, such as, but not limited to, mobile telephones, wireless devices, Personal Data Assistants (PDAs), hand-held or portable computers, GPS receivers/navigators, cameras, MP4 video players, video cameras, game consoles, wrist watches, clocks, calculators, television monitors, flat panel displays, computer monitors, auto displays (e.g., odometer display, etc.), navigators, cockpit controls and/or displays, displays of camera views (e.g., display of a rear view camera in a vehicle), electronic photographs, electronic billboards or signs, projectors, architectural structures, packaging and aesthetic structures, among others.

Compared with the related art, the present disclosure has the followings beneficial effects.

The pixel arrangement structure provided by the present disclosure includes a plurality of first virtual polygons, the first virtual polygons are arranged in a manner of sharing edges to form a pixel array, the third sub-pixels are positioned inside the first virtual polygons, and the connecting line of centers of the third sub-pixels in two adjacent first virtual polygons is parallel to the row direction or the column direction, thereby solving the problem of jagged display of the OLED display device. Two first sub-pixels are arranged at each of the first vertices in each of the first virtual polygons, so that more sub-pixels are included in a basic pixel unit, and there are more sub-pixels that are not borrowed by the adjacent pixel units, thereby increasing the real PPI of the display panel, rendering the display effect more exquisite, and favorably improving the display effect of the OLED display device.

The advantages of the metal mask, the display panel and the display device are the same as those of the pixel arrangement structure compared with the related art, which are not described herein again.

In summary, the pixel arrangement structure, the metal mask, the display panel and the display device disclosed in the present disclosure have at least the following advantages:
(1) The apertures of the metal mask are completely densely arranged by adjusting the shapes of the sub-pixels, which is beneficial to improving the aperture ratio of the sub-pixels, making the space utilization rate of the pixel arrangement higher;
(2) The number of the blue sub-pixels is increased, which in one aspect can correspond to various driving circuit outcomes and reduce the probability of occurrence of poor screen luminescence, and in another aspect is beneficial to improving the real PPI of the OLED display device; and
(3) The relative positions of the green sub-pixels are fixed, which solves the problem of jagged display of the OLED display device.

The pixel arrangement structure disclosed in the embodiments of the present disclosure includes a plurality of first virtual polygons, the first virtual polygons are arranged in a manner of sharing edges to form a pixel array, the third sub-pixels are positioned inside each of the first virtual polygons, and the center connecting line of the third sub-pixels in two adjacent first virtual polygons is parallel to the row direction or the column direction, so that the problem of jagged display of the OLED display device is solved; two first sub-pixels are arranged at the first vertex in each of the first virtual polygons, the number of sub-pixels contained in the basic pixel unit is more, the number of sub-pixels which are not borrowed by the adjacent pixel units is also more, so that the real PPI is increased, the display effect is more exquisite, which is thus beneficial to improving the display effect of the OLED display device.

The metal mask, the display panel and the display device described above have the same advantages as the pixel arrangement structure compared with the prior art, which are not repeated here.

Those described above are more detailed illustrations of the present disclosure in connection with specific embodiments, and it is not intended that the present disclosure be limited to these specific illustrations. For those skilled in the art to which the present disclosure pertains, simple deductions or substitutions can be made without departing from the spirit of the present disclosure, which all shall be considered as belonging to the protection scope of the present disclosure.

1. A pixel arrangement structure comprising:
a first sub-pixel located at a first vertex of a first virtual polygon;
a second sub-pixel located at a second vertex of a first virtual polygon, the first vertex and the second vertex being arranged alternately and spaced apart; and
a third sub-pixel located inside the first virtual polygon;
wherein two first sub-pixels are arranged at each first vertex, and a connecting line of centers of the third sub-pixels in two adjacent first virtual polygons is parallel to a row direction or a column direction.

2. The pixel arrangement structure according to claim 1, wherein the pixel arrangement structure comprises a plurality of pixel units, each of the pixel units consists of two first sub-pixels, two second sub-pixels and one third sub-pixel; or each of the pixel units consists of two first sub-pixels, one second sub-pixel and two third sub-pixels.

3. The pixel arrangement structure according to claim 1, wherein the two first sub-pixels at each first vertices are disposed symmetrically with respect to the first vertex.

4. The pixel arrangement according to claim 2, wherein each of the pixel units has one or two first sub-pixels at one first vertex.

5. The pixel arrangement structure according to claim 2, wherein the two first sub-pixels included in each of the pixel units are located at the same vertex of the first virtual polygon, or located at opposite vertices of the first virtual polygon, respectively.

6. The pixel arrangement according to claim 2, wherein connecting lines of centers of all sub-pixels in each of the pixel units form a second virtual polygon, and the third sub-pixel is located at a vertex of the second virtual polygon or inside the second virtual polygon.

7. The pixel arrangement according to claim 1, wherein a group of first sub-pixels is provided at each first vertex, each group of first sub-pixels comprises two first sub-pixels, two groups of first sub-pixels are arranged in each first virtual polygon, the first sub-pixels in one of the two groups of first sub-pixels are symmetrical with respect to a first virtual symmetry line, the first sub-pixels in the other one of the two groups of first sub-pixels are symmetrical with respect to a second virtual symmetry line, and the first virtual symmetry line and the second virtual symmetry line form an included angle.

8. The pixel arrangement structure according to claim 1, wherein in the first virtual polygon, a first distance between a center of the third sub-pixel and each of centers of two second sub-pixels adjacent to the third sub-pixel is the same, a second distance between the center of the third sub-pixel and each of centers of two first sub-pixels adjacent to the third sub-pixel is the same, and the first distance and the second distance are not equal to each other.

9. The pixel arrangement structure according to claim 8, wherein among center connecting lines formed by the center of the third sub-pixel and centers of sub-pixels adjacent to the third sub-pixel in the first virtual polygon, an included angle between any two adjacent ones of the center connecting lines is 90°.

10. The pixel arrangement structure according to claim 8, wherein among center connecting lines formed by the center of the third sub-pixel and centers of sub-pixels adjacent to the third sub-pixel in the first virtual polygon, an included angles formed between any two adjacent ones of the center connecting lines is different, and the center of the third sub-pixel overlaps with an extending direction of a connecting line of centers of the sub-pixels with the same color that are adjacent to the third sub-pixel.

11. The pixel arrangement structure according to claim 1, wherein in the first virtual polygon, a fifth distance between a center of the third sub-pixel and each of centers of two second sub-pixels adjacent to the third sub-pixel is the same, a sixth distance between the center of the third sub-pixel and each of centers of two first sub-pixels adjacent to the third sub-pixel is different, and the fifth distance and the sixth distance are not equal to each other.

12. The pixel arrangement structure according to claim 1, wherein among center connecting lines formed by the center of the third sub-pixel and centers of sub-pixels adjacent to the third sub-pixel in the first virtual polygon, a smaller included angle formed between two adjacent ones of the center connecting lines is greater than 72 degrees and less than 83 degrees.

13. The pixel arrangement structure according to claim 1, wherein in the first virtual polygon, a first connecting line is formed between a center of the third sub-pixel and each of centers of the second sub-pixels adjacent to the third sub-pixel, a second connecting line is formed between the center of the third sub-pixel and each of centers of the first sub-pixels adjacent to the third sub-pixel form a second connection line, a first included angle formed between each of two first connecting lines and one of second connecting lines is 90 degrees, a second included angle and a third included angle are respectively formed between the two first connecting lines and another one of the second connecting lines, and the first included angle, the second included angle and the third included angle are different from each other.

14. The pixel arrangement structure according to claim 1, wherein each of the two first sub-pixels located at a same vertex of the first virtual polygon comprises an anode layer, and two anode layers corresponding to the two first sub-pixels are respectively connected to a same data signal line.

15. The pixel arrangement structure according to claim 1, wherein an aperture area of the first sub-pixel is larger than an aperture area of the second sub-pixel, and is larger than an aperture area of the third sub-pixel.

16. The pixel arrangement according to claim 1, wherein the first sub-pixel is a blue sub-pixel, the second sub-pixel is a red sub-pixel, and the third sub-pixel is a green sub-pixel.

17. The pixel arrangement structure according to claim 1, wherein the first virtual polygon is a first virtual quadrilateral having a first edge and a third edge parallel to each other, and a second edge and a fourth edge connected between the first edge and the third edge.

18. A metal mask for fabricating a pixel arrangement structure, wherein the pixel arrangement structure comprises:
a first sub-pixel located at a first vertex of a first virtual polygon;
a second sub-pixel located at a second vertex of a first virtual polygon, the first vertex and the second vertex being arranged alternately and spaced apart; and
a third sub-pixel located inside the first virtual polygon;
wherein two first sub-pixels are arranged at each first vertex, and a connecting line of centers of the third sub-pixels in two adjacent first virtual polygons is parallel to a row direction or a column direction, and
wherein the metal mask comprises:
a plurality of aperture regions, a shape of each of the aperture regions corresponding to each sub-pixel is matched with an outer contour shape of the sub-pixel, the two first sub-pixels located at the same vertex of the first virtual polygon share a same aperture region, the aperture regions corresponding to the sub-pixels with different colors are tangent with respect to a tangent line segment, and any two of the aperture regions corresponding to three adjacent sub-pixels are tangent with respect to each other.

19. The metal mask according to claim 18, wherein the first sub-pixel is in a crescent shape and is enclosed by four line segments, a first line segment of the four line segments is arranged opposite to a second line segment of an outer contour of the second sub-pixel, and an extending direction of the first line segment is parallel to an extending direction of the second line segment, so that the aperture region corresponding to the first sub-pixel is tangent to the aperture region corresponding to the second sub-pixel.

20. A display panel comprising a pixel arrangement structure, wherein the pixel arrangement structure comprises:
a first sub-pixel located at a first vertex of a first virtual polygon;
a second sub-pixel located at a second vertex of a first virtual polygon, the first vertex and the second vertex being arranged alternately and spaced apart; and
a third sub-pixel located inside the first virtual polygon;
wherein two first sub-pixels are arranged at each first vertex, and a connecting line of centers of the third sub-pixels in two adjacent first virtual polygons is parallel to a row direction or a column direction.

21. (canceled)
